(19) United States
(12) Patent Application Publication
(10) Pub. No.: US 2018/0122638 A1
(43) Pub. Date: May 3, 2018

(54) SUBSTRATE PROCESSING APPARATUS

(71) Applicant: EUGENE TECHNOLOGY CO., LTD., Yongin-Si, Gyeonggi-Do (KR)

(72) Inventors: Woo Duck JUNG, Suwon-Si, Gyeonggi-Do (KR); Kyu Jin CHOI, Yongin-Si, Gyeonggi-Do (KR); Song Hwan PARK, Yongin-Si, Gyeonggi-Do (KR); Kyoung Hun KIM, Yongin-Si, Gyeonggi-Do (KR); Seong Min HAN, Yongin-Si, Gyeonggi-Do (KR); Sung Ha CHOI, Yongin-Si, Gyeonggi-Do (KR)

(21) Appl. No.: 15/566,696

(22) PCT Filed: Apr. 19, 2016
(86) PCT No.: PCT/KR2016/004074

§ 371 Date: Oct. 13, 2017

(30) Foreign Application Priority Data
Apr. 20, 2015 (KR) 10-2015-0055297

(51) Int. Cl. H01L 21/205; H01L 21/3065

(52) U.S. Cl. CPC H01L 21/205; H01L 21/3065

(57) ABSTRACT

Disclosed is a substrate processing apparatus comprising: a chamber which provides a substrate processing space; a process gas supply line which is for supplying a process gas into the chamber; a first diffusion plate which has formed on an edge portion thereof an injection hole for injecting the process gas; a substrate support which faces the first diffusion plate and is for supporting a substrate; a second diffusion plate which is provided between the first diffusion plate and the substrate support and has formed thereon a plurality of distribution holes; and a plasma generation unit which is for forming plasma in the space between the first diffusion plate and the second diffusion plate.

### TECHNICAL FIELD

The present disclosure relates to a substrate processing apparatus, and more particularly, to a substrate processing apparatus that is capable of improving uniformity in substrate processing.

### BACKGROUND ART

Substrate processing apparatuses may be apparatuses for performing substrate processing such as etching or deposition by using physical or chemical reaction such as a plasma phenomenon in a vacuum state. In general, in a substrate processing process using a substrate processing apparatus, a reaction gas may be injected through a showerhead installed in a chamber to perform substrate processing. Also, the injected reaction gas may generate plasma within the chamber by applying power. Thus, the substrate processing such as processes in which a surface of the substrate is etched by a material having the plasma state such as radical formed in the chamber, or the material having the plasma state such as the radical is deposited on the surface of the substrate according to the purpose for the substrate processing may be performed.

However, in the substrate processing apparatus in accordance with the related art, when the plasma is generated to perform the substrate processing, the substrate and circuit elements formed on the substrate may be damaged by generation of arc, collision of ions, injection of the ions, and the like to cause process defects.

Also, in the substrate processing apparatus in accordance with the related art, since uniform movement and distribution of the reaction gas plasma are difficult by using only the showerhead that distributes the reaction gas, the plasma may not be uniformly distributed on the entire surface of the substrate, but be concentrated into one point. Thus, a film that is deposited on the substrate or etched may have a non-uniform thickness.

(Patent Document 1) Korean Patent Registration No. 10-0880767

### DISCLOSURE OF THE INVENTION

### Technical Problem

The present disclosure provides a substrate processing apparatus in which plasma is uniformly distributed on an enter surface of a substrate to improve uniformity in substrate processing.

### Technical Solution

In accordance with an exemplary embodiment, a substrate processing apparatus includes: a chamber configured to provide a substrate processing space; a process gas supply line configured to supply a process gas into the chamber; a first diffusion plate having an injection hole, through which the process gas is injected, in an edge portion thereof; a substrate support disposed to face the first diffusion plate and configured to support a substrate; a second diffusion plate disposed between the first diffusion plate and the substrate support, and having a plurality of distribution holes; and a plasma generation unit configured to generate plasma in a space between the first diffusion plate and the second diffusion plate.

The substrate processing apparatus may further include a sidewall member connected to an edge of the second diffusion plate and having a plurality of gas induction holes.

The second diffusion plate may have effective area densities of the distribution holes, which are different from each other according to positions of the distribution holes.

The effective area density of the distribution hole in a central portion of the second diffusion plate may be greater than that of the distribution hole in an edge portion of the second diffusion plate.

The substrate processing apparatus may further include an insertion body inserted into each of the distribution holes to adjust an opening area of the second diffusion plate.

The insertion body may have a through hole passing through a central portion of the insertion body.

The second diffusion plate may have a multistage structure comprising a plurality of stages, and the distribution holes in the stages adjacent to each other may be different in position from each other.

The substrate processing apparatus may further include a position adjustment unit configured to adjust a distance between the first diffusion plate and the second diffusion plate.

The substrate processing apparatus may further include a plurality of exhaust ports disposed symmetrical to each other along a circumference of the substrate support at positions adjacent to an inner wall of the chamber and having a multistage structure.

The substrate processing apparatus may further include a blocking ring extending from an edge portion of the substrate support along a circumference of the substrate support.

### Advantageous Effects

In the substrate processing apparatus in accordance with the exemplary embodiment, the first diffusion plate for distributing the process gas and the second diffusion plate for distributing the plasma may be used to realize the uniform distribution of the plasma. Thus, the substrate processing such as the etching and the deposition may be uniformly performed on the entire surface of the substrate.

Also, when the plasma is generated, the substrate may not be directly exposed to the plasma through the second diffusion plate. Thus, the substrate and the circuit elements formed on the substrate may be prevented from being damaged by the generation of the arc, the collision of the ions, and the injection of the ions within the chamber. Thus, the process defects of the substrate and the circuit elements formed on the substrate may be minimized. Also, the second diffusion plate may be grounded to filter the ions and electrons charged in the plasma. Thus, since only the neutral reaction species are introduced onto the substrate, the harmful influence of the charged ions and electrons on the substrate and the surrounding of the substrate may be minimized. Also, the substrate and the surrounding of the substrate may be prevented from being damaged by the plasma.

In addition, the effective area densities of the distribution holes may be simply adjusted by using the insertion body that is inserted into the distribution hole of the second diffusion plate. Therefore, even though the process conditions are changed, the neutral reaction species (or the plasma) may be uniformly distributed. Also, the second diffusion plate may have the multistage structure to control the flow of the neutral reaction species (or the plasma).

### BRIEF DESCRIPTION OF THE DRAWINGS

FIG. 1 is a cross-sectional view of a substrate processing apparatus in accordance with an exemplary embodiment.

FIG. 2 is a plan view of a second diffusion plate in accordance with an exemplary embodiment.

FIG. 3 is a perspective view of a sidewall member in accordance with an exemplary embodiment.

FIG. 4 is a coupling perspective view of the second diffusion plate and the sidewall member in accordance with an exemplary embodiment.

FIG. 5 is a plan view of the second diffusion plate having a large distribution hole in accordance with an exemplary embodiment.

FIG. 6 is a plan view of the second diffusion plate having a small distribution hole in accordance with an exemplary embodiment.

FIG. 7 is a plan view of the second diffusion plate having the large distribution hole in a central portion and the small distribution hole in an edge portion in accordance with an exemplary embodiment.

FIG. 8 is a view of an insertion body inserted into the distribution hole of the second diffusion plate in accordance with an exemplary embodiment.

FIG. 9 is a cross-sectional view of the second diffusion plate having a multistage structure including a plurality of stages in which the distribution holes of the stages are different in position from each other in accordance with an exemplary embodiment.

FIG. 10 is a cross-sectional view of the second diffusion plate having the multistage structure including a plurality of stages in which the distribution holes of the stages are different in position and size from each other in accordance with an exemplary embodiment.

### MODE FOR CARRYING OUT THE INVENTION

Hereinafter, specific embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the descriptions, the same elements are denoted with the same reference numerals. In the figures, the dimensions of layers and regions are exaggerated for clarity of illustration. Like reference numerals refer to like elements throughout.

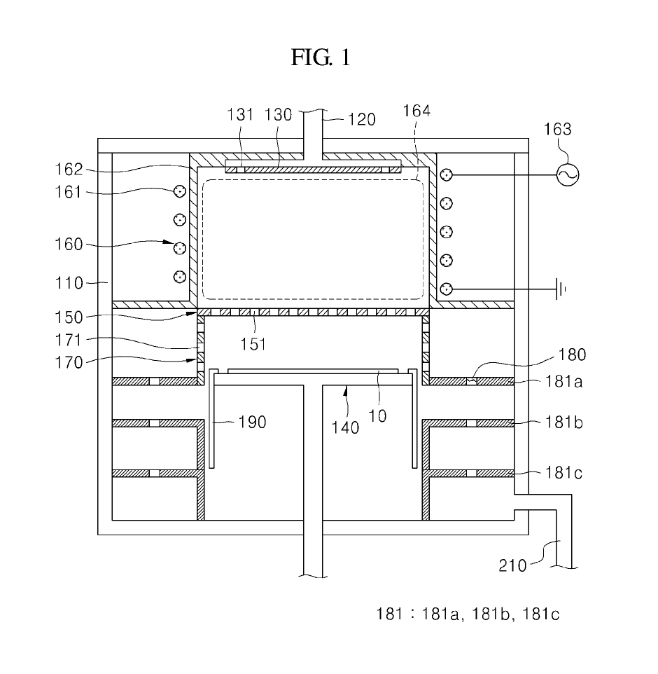

FIG. 1 is a cross-sectional view of a substrate processing apparatus in accordance with an exemplary embodiment.

Referring to FIG. 1, a substrate processing apparatus in accordance with an exemplary embodiment includes a chamber 110 configured to provide a substrate processing space, a process gas supply line 120 supplying a process gas into the chamber 110, a first diffusion plate 130 having an injection hole 131, through which the process gas is injected, in an edge portion, a substrate support 140 disposed facing the first diffusion plate 130 to support a substrate 10, a second diffusion plate 150 disposed between the first diffusion plate 130 and the substrate support 140 and having a plurality of distribution holes 151, and a plasma generation unit 160 generating plasma 164 in a space between the first diffusion plate 130 and the second diffusion plate 150.

The chamber 110 provides a space in which the substrate processing is performed. The inside of the chamber may be in a vacuum state, and the plasma may be generated in the chamber to effectively perform the substrate processing. Also, the chamber 110 may include an exhaust unit 210 for exhausting a gas. For example, the exhaust unit 210 may be disposed in a lower portion of the chamber 110. Also, the chamber 110 may be formed of various materials such as a metal, ceramic, glass, a polymer, and a compound. The chamber 110 may have a right angle shape, a dome shape, a cylindrical shape, and so on.

The process gas supply line 120 supplies the process gas from a process gas supply source (not shown) to the chamber 110. The process gas may include an etching gas and a source gas for depositing a thin film. Here, the process gas supply line 120 may supply the etching gas when an etching process is performed and supply the source gas for depositing the thin film when a thin film deposition process is performed. That is, the process gas supply line 120 may supply the process gas that is adequate for the purpose of the substrate processing. The etching gas may include a natural oxide etching gas such as nitrogen trifluoride (NF3) and ammonia. The source gas for depositing the thin film may include a silicon deposition gas such as monosilane (SiH4) and phosphine (PH3). The gases may be adequately selected according to a kind of thin film to be deposited. Also, an inert gas such as hydrogen (H2), nitrogen (N2), and argon (Ar) together with the etching gas or the source gas for depositing the thin film may be supplied as the process gas.

The first diffusion plate 130 distributes the process gas. An injection hole 131 through which the process gas is injected may be defined in the edge portion of the first diffusion plate 130. Since the process gas is distributed and injected through the first diffusion plate 130, the process gas may uniformly reach the substrate 10. To uniformly distribute the process gas, the process gas supply line 120 may be disposed in a central portion of the chamber 110. In this case, when the injection hole 131 is defined in the central portion, a relatively large amount of process gas may be injected from the central portion communicating with the process gas supply line 120 when compared to other portions. Thus, an amount of process gas reaching the substrate 10 may be non-uniform according to positions, and also, the substrate processing through the process gas may be non-uniformly performed according to positions. However, like an exemplary embodiment, when the injection hole 131 is defined in the edge portion, the process gas may be uniformly distributed and injected by being bypassed without communicating with the process gas supply line 120 to allow the process gas to uniformly reach the substrate 10. The accurate position, injection direction, and number of the injection hole 131 may be adequately determined so that the process gas uniformly flows in the chamber 110.

The substrate support 140 may be disposed facing the first diffusion plate 130 to support the substrate 10. The substrate support 140 may be disposed in an inner lower portion of the chamber to support the substrate 10. Also, the substrate support 140 may include a chargeable electrostatic chuck so that the substrate 10 is supported by the substrate support 140, and the substrate is maintained in an electrostatic state.

The second diffusion plate 150 may be disposed between the first diffusion plate 130 and the substrate support 140, and have a plurality of distribution holes 151. The uniform flow of the process gas within the chamber 110 may be realized by using only the first diffusion plate 130. If only the first diffusion plate 130 is used, the flow of the process gas (or the plasma) may be concentrated into an exhaust direction by the exhaust unit 210 due to a distance between the first diffusion plate 130 and the substrate 10. As a result, the non-uniform distribution of the process gas (or the plasma) on the substrate 10 may occur. However, if the second diffusion plate 150 is used together with the first diffusion plate 130, the flow of the process gas (or the plasma) may be controlled to realize the uniform distribution of the process gas (or the plasma) on the substrate 10.

Also, the second diffusion plate 150 may be grounded, or a voltage may be applied to the second diffusion plate 150 to filter ions and electrons that are charged in the plasma. That is, when the plasma passes through the second diffusion plate 150, the ions and electrons may be blocked so that only neutral reaction species react on the substrate 10. The second diffusion plate 150 may be configured so that the plasma collides with the second diffusion plate 150 at least once to reach the substrate 10. Also, when the plasma collides with the second diffusion plate 150 that is grounded (or to which a voltage having different polarity is applied), ions and electrons having large energy may be absorbed into the second diffusion plate 150. Thus, the harmful influence of the charged ions and electrons on the substrate 10 and the surrounding of the substrate 10 may be minimized. Also, since only the neutral reaction species react with the substrate 10 or the thin film on the substrate 10, even though the substrate processing apparatus is used for a long time, the surrounding parts within the chamber 110 may be usable to prevent the surface of the substrate 10 from being damaged. The second diffusion plate 150 may also block light of the plasma. Thus, the light of the plasma may collide with the second diffusion plate 150 and thus may not be transmitted through the second diffusion plate 150. Also, the second diffusion plate 150 may be grounded through contact with the chamber 110 without providing a secondary electrode.

Also, when the plasma is generated, the substrate 10 may not be directly exposed to the plasma through the second diffusion plate 150. Thus, the substrate 10 and the circuit elements formed on the substrate 10 may be prevented from being damaged by the generation of the arc, the collision of the ions, and the injection of the ions within the chamber 110. Thus, the process defects of the substrate 10 and the circuit elements formed on the substrate 10 according to the substrate processing process may be minimized.

The plasma generation unit 160 may generate plasma 164 in a space between the first diffusion plate 130 and the second diffusion plate 150. The plasma generation unit 160 may excite the process gas to generate the plasma 164. Thus, the plasma generation unit 160 may include a discharge tube 162 and an antenna 161 (or an inductive coupling coil) that is disposed to surround the discharge tube 162. The discharge tube 162 may be formed of sapphire, quartz, or ceramic and have a predetermined dome (or box) shape. The discharge tube 162 may be disposed in an inner upper portion of the chamber 110. The discharge tube 162 may have an upper portion connected to the process gas supply line 120 and a lower portion that defines a plasma generation space (i.e., the space between the first diffusion plate 130 and the second diffusion plate 150) together with the second diffusion plate 150. Here, the process gas may be distributed into the space between the upper portion of the discharge tube 162 and the first diffusion plate 130 and then be injected through the injection hole 131 of the first diffusion plate 130. The antenna 161 may be disposed to surround the discharge tube 162 in the chamber 110. Also, the antenna 161 may receive power from a power source 163 to excite the process gas within the discharge tube 162, thereby generating the plasma 164. Alternatively, after an electrode is provided in the inner space of the chamber 110, power may be applied to the provided electrode to generate the plasma.

In the substrate processing apparatus in accordance with an exemplary embodiment, the process gas may bypass the process gas supply line 120 disposed at the central portion of the chamber 110 through the first diffusion plate 130 and then be uniformly injected through the discharge hole 131. Also, the process gas may be widely spread in the space between the first diffusion plate 130 and the second diffusion plate 150. In addition, only the neutral reaction species may be uniformly introduced onto the substrate 10 through the distribution holes 151 of the second diffusion plate 150. Thus, the substrate processing apparatus in accordance with an exemplary embodiment may perform the uniform substrate processing on the entire surface of the substrate 10. Each of the first diffusion plate 130 and the second diffusion plate 150 may affect the flow of the gas (e.g., the process gas, the plasma, and the neutral reaction species) to allow the neutral reaction species to be uniformly distributed on the substrate 10.

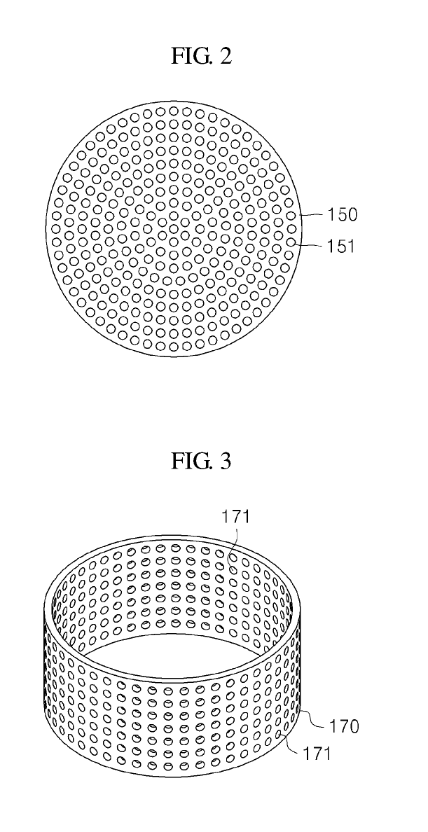

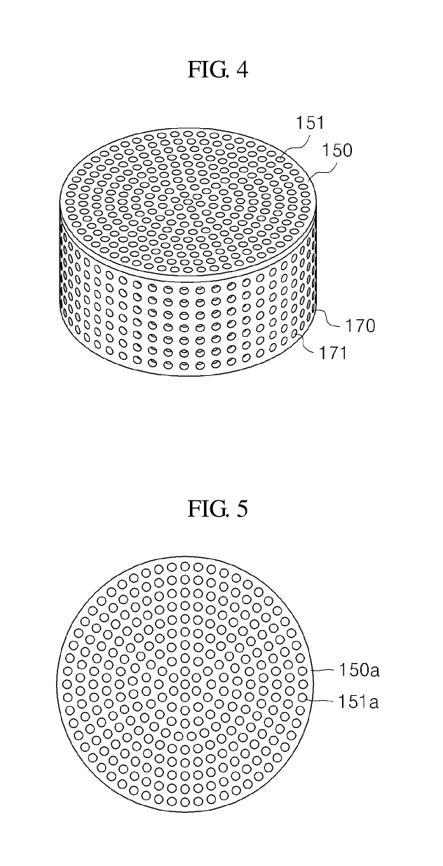

FIG. 2 is a plan view of the second diffusion plate in accordance with an exemplary embodiment, FIG. 3 is a perspective view of the sidewall member in accordance with an exemplary embodiment, and FIG. 4 is a coupling perspective view of the second diffusion plate and the sidewall member in accordance with an exemplary embodiment.

Referring to FIGS. 2 to 4, the substrate processing apparatus in accordance with an exemplary embodiment may further include the sidewall member 170 connected to an edge of the second diffusion plate 150 and having a plurality of gas induction holes 171. The sidewall member 170 may be coupled to the second diffusion plate 150 and provide a space in which the neutral reaction species passing through the second diffusion plate 150 react on the substrate 10. If the sidewall member 170 is not provided, the neutral reaction species may not sufficiently react due to the exhaust by the exhaust unit 210 and then be exhausted. However, if the sidewall member 170 is provided, the flow of the neutral reaction species may be controlled to allow the neutral reaction species to sufficiently react on the substrate 10. The plurality of gas induction holes 171 are defined in the sidewall member 170. Thus, the flow of the gas due to the suction (or pumping) of the exhaust unit 210 may be adjusted according to sizes, positions, and number of the gas induction holes 171. As a result, the flow of the neutral reaction species may be controlled. Therefore, the flow of the gas in the plasma generation space may also be controlled. Also, process (e.g., etching or deposition) byproducts that are in a gaseous state may be exhausted to the gas induction holes 171 by the suction (or the pumping) of the exhaust unit 210. Also, a moving speed and exhaust speed of the neutral reaction species may be adjusted according to the size, positions, and number of the gas induction holes 171. The neutral reaction species may pass through the distribution holes 151 of the second diffusion plate 150 to react on the substrate 10. Thus, the flow of the neutral reaction species reaching the substrate 10 through the gas induction holes 171 of the sidewall member 170 may be controlled. Thus, the moving speed of the neutral reaction species may be adjusted, and the neutral reaction species may stay on the substrate 10 to provide a time that is taken to sufficiently react on the substrate 10. The second diffusion plate 150 and the sidewall member 170 may be integrated with each other.

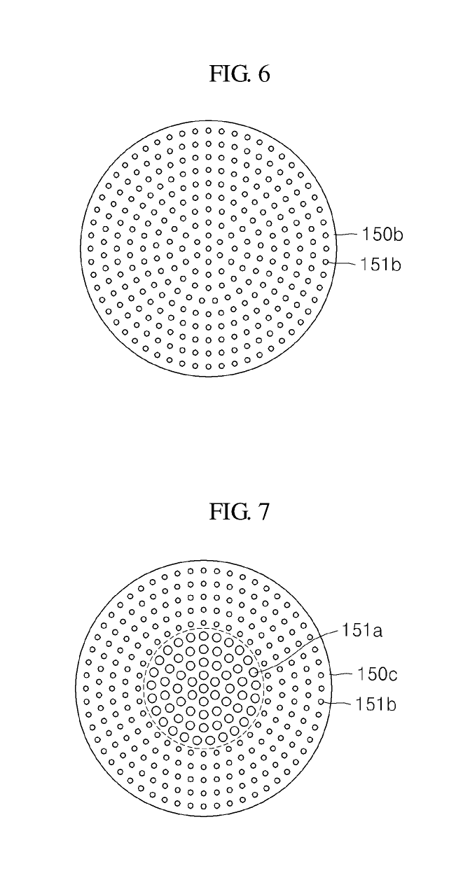

FIG. 5 is a plan view of the second diffusion plate having a large distribution hole in accordance with an exemplary embodiment, FIG. 6 is a plan view of the second diffusion plate having a small distribution hole in accordance with an exemplary embodiment, and FIG. 7 is a plan view of the second diffusion plate having the large distribution hole in a central portion and the small distribution hole in an edge portion in accordance with an exemplary embodiment. FIGS. 5 to 7 illustrate a modified example of the second diffusion plate in accordance with an exemplary embodiment.

Referring to FIGS. 5 to 7, the second diffusion plate 150 may have effective area densities of distribution holes 151, which are different from each other according to the positions. Here, the effective area densities may be a total area of the distribution holes 151 per a unit area, i.e., an opening area (i.e., an area opened by the distribution holes) per a unit area of the second diffusion plate 150. As illustrated in FIG. 5, a large distribution hole 151a may be defined overall in the second diffusion plate 150. If the distribution hole 151 is too large, the flow of the neutral reaction species may be concentrated into the exhaust direction by the exhaust unit 210 to cause non-uniform distribution of the neutral reaction species on the substrate 10. As illustrated in FIG. 6, a small distribution hole 151b may be defined overall in the second diffusion plate 150. If the distribution hole 151b is too small, the moving speed of the neutral reaction species may be slow to increase the process time. Also, when the distribution holes 151 having the same size are defined overall in the second diffusion plate 150, a more amount of neutral reaction species may be supplied to the edge portion of the substrate than the central portion of the substrate 10 due to the positions of the injection holes 131 of the first diffusion plate 130, which is defined in the edge, and the exhaust direction by the exhaust unit 210 provided in the edge to cause the non-uniform distribution of the neutral reaction species. However, the distribution holes 151 may have sizes or densities different from each other according to the positions to allow the neutral reaction species to be uniformly distributed. Thus, the second diffusion plate 150 may have the distribution holes 151 that are different in size or density according to the positions and thus have effective area densities of the distribution holes 151, which are different from each other according to the positions. For example, each of the distribution holes 151 defined in the central portion of the second diffusion plate 150 may have a size greater than that of each of the distribution holes 151 defined in the edge portion, or the distribution holes 151 may have sizes that gradually increase or decrease according to distances from the center of the second diffusion plate 150.

In the second diffusion plate 150, an effective area density of the distribution holes 151 at the central portion may be greater than that of the edge portion. For example, as illustrated in FIG. 7, the distribution hole 151a in the central portion may have a size greater than that of the distribution hole 151b in the edge portion so that an effective area density of the distribution hole 151a in the central portion is greater than that of the distribution hole 151b in the edge portion. In this case, the neutral reaction species introduced into the central portion of the second diffusion plate 150 may increase to allow the neutral reaction species to be uniformly distributed on the substrate 10. In general, since the injection hole 131 of the first diffusion plate 130 is defined in the edge portion, and the exhaust direction by the exhaust unit 210 is directed in the direction of the edge portion, the flow of the gas may be concentrated into the edge portion. Thus, since an amount of neutral reaction species reaching the substrate 10 is less at the central portion of the second diffusion plate 150, the reaction at the central portion of the substrate 10 may not well occur. For this reason, when the distribution hole 151a defined in the central portion of the second diffusion plate 150 has an effective area density greater than that of the distribution hole 151b defined in the edge portion of the second diffusion plate 150, an inflow amount of neutral reaction species introduced into the central portion of the second diffusion plate 150 may increase. Thus, the neutral reaction species may be uniformly distributed on the substrate 10.

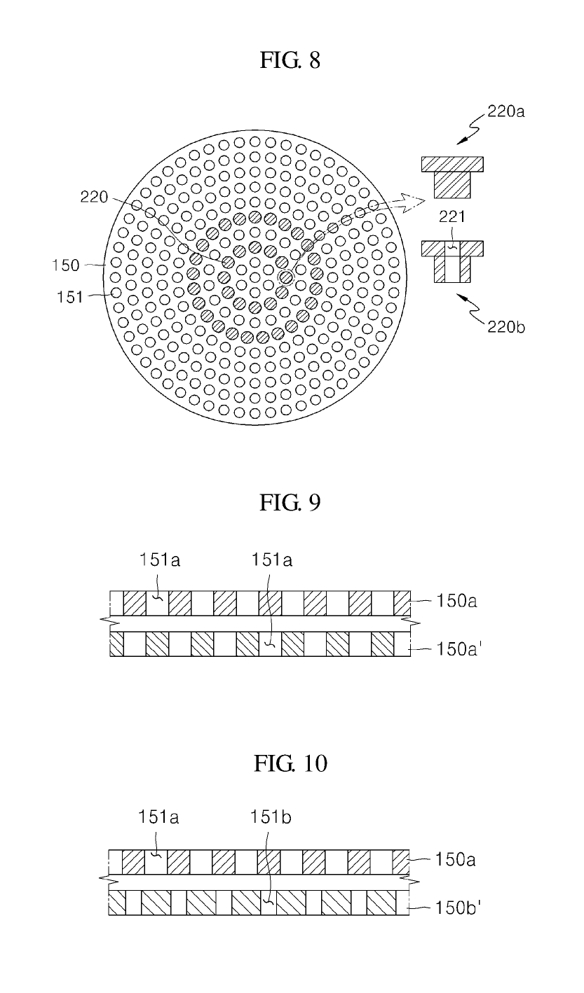

FIG. 8 is a view of an insertion body inserted into the distribution hole of the second diffusion plate in accordance with an exemplary embodiment.

Referring to FIG. 8, the substrate processing apparatus may further include an insertion body 220 inserted into the distribution hole 151 to adjust an opening area of the second diffusion plate 150. The insertion body 220 may have a plug shape. The insertion body 220 may be inserted into the distribution hole 151 to block the distribution hole 151. In this case, it may be unnecessary to manufacture the second diffusion plate 150 again so as to change the arranged structure of the distribution holes 151. That is, the arranged structure of the distribution holes 151 may be easily changed by only inserting the insertion body 220a. In addition, the distribution holes 151 may have effective area densities of the distribution holes 151, which are different from each other according to the positions. Thus, the insertion body 220a may be only inserted to easily adjust the flow of the neutral reaction species.

The insertion body 220b may include a through hole 221 passing through a central portion of the insertion body. When the insertion body 220b having the through hole 221 is inserted into the distribution hole 151, the distribution hole 151 may be adjusted in size to adjust a fine flow of the neutral reaction species. Thus, the fine difference according to the condition of the chamber 110 and the process condition such as the pumping speed may be adjusted by inserting the insertion body 220b. Thus, the neutral reaction species may be more uniformly distributed on the substrate 10. Also, the through hole 221 may have various sizes. Thus, the flow of the neutral reaction species may be more finely adjusted through the through hole 221 having the various sizes.

The blocked insertion body 220a and the insertion body 220b having the through hole 221 may be used together with each other. In this case, the flow of the neutral reaction species may be more accurately adjusted.

FIG. 9 is a cross-sectional view of the second diffusion plate having a multistage structure including a plurality of stages in which the distribution holes of the stages are different in position from each other in accordance with an exemplary embodiment, and FIG. 10 is a cross-sectional view of the second diffusion plate having the multistage structure including a plurality of stages in which the distribution holes of the stages are different in position and size from each other in accordance with an exemplary embodiment. FIGS. 9 to 10 illustrate a conceptual view for explaining a multistage structure of the second diffusion plate in accordance with an exemplary embodiment.

Referring to FIGS. 9 and 10, the second diffusion plate 150 may have a plurality of multistage structures. Here, distribution holes 151 in stages that are adjacent to each other may be different in position from each other. The distribution holes 151 defined in the stages adjacent to each other may be different in position from each other as illustrated in FIG. 9, may be different in position and size from each other as illustrated in FIG. 10, or may be different in size from each other, but be defined at the same position. In this case, the neutral reaction species may be controlled to flow to the plurality of second diffusion plates 150. An amount and movement (or introduction) speed of the neutral reaction species reaching the substrate 10 may be adjusted according to a position of the substrate 10. When a distance between the second diffusion plate 150 and the substrate 10 is short, the introduction speed of the neutral reaction species may be fast, and a reaction time of the neutral reaction species on the substrate 10 may be shortened. Thus, a difference in uniformity of the substrate processing at the position in which the distribution hole 151 is defined and at the position in which the distribution hole 151 is not defined may occur. Thus, when the second diffusion plate 150 has the plurality of multistage structures, even though the distance between the second diffusion plate 150 and the substrate 10 is short, the introduction speed of the neutral reaction species may be lowered due to a bottleneck phenomenon in flow of the neutral reaction species to allow the neutral reaction species to be uniformly distribution on the substrate 10.

The substrate processing apparatus in accordance with an exemplary embodiment may further include a position adjustment unit (not shown) for adjusting a distance between the first diffusion plate 130 and the second diffusion plate 150. The position adjustment unit may adjust a position of the second diffusion plate 150 to adjust the distance between the first diffusion plate 130 and the second diffusion plate 150. When the distance between the first diffusion plate 130 and the second diffusion plate 150 is adjusted, a plasma generation space may be adjusted to provide a sufficient space in which the process gas is widely spread. Also, when the process gas may be uniformly distributed in the space between the first diffusion plate 130 and the second diffusion plate 150 at a predetermined distance between the diffusion plate 130 and the second diffusion plate 150, the plasma 164 may be generated. Also, the second diffusion plate 150 may be adjusted in position to adjust a distance between the substrate 10 and the second diffusion plate 150. Here, the distance between the first diffusion plate 130 and the second diffusion plate 150 may also be adjusted according to the position of the second diffusion plate 150. If the distance between the substrate 10 and the second diffusion plate 150 is short, the substrate processing such as the etching may be more uniformly performed, and thus, a substrate processing rate (e.g., an etching rate) may more increase. Also, in the etching process, a selection ratio (e.g., an etching ratio of a natural oxide layer and a nitride layer) may also more increase. If a distance between the substrate 10 and the second diffusion plate 150 is approximately 50 mm or less, and the distribution hole 151 has a diameter of 10 mm or more, when a thin film is deposited on a surface of the substrate 10 after the surface of the substrate 10 is etched, a film color phenomenon may occur due to the arranged configuration of the second diffusion plate 150 and the distribution hole 151. However, if the distance between the substrate 10 and the second diffusion plate 150 is approximately 50 mm or less, the distribution hole 151 may have a diameter of 10 mm or less to solve the above-described limitation. Here, the second diffusion plate 150 may have the multistage structure to allow the bottleneck phenomenon to occur in the flow of the neutral reaction species, thereby realizing the more uniform substrate processing such as the etching and deposition. The film color may be seen when the surface of the substrate 10 is unevenness, or the deposited thin film has a non-uniform thickness due to the non-uniform etching. When the distribution hole 151 has a diameter of 10 mm or less, the flow of the neutral reaction species may be uniform to prevent the film color phenomenon from occurring.

The substrate processing apparatus in accordance with an exemplary embodiment may further include a plurality of exhaust ports 180 that have a multistage structure and are disposed symmetrical to each other along a circumference of the substrate support 140 at a position adjacent to an inner wall of the chamber 110. The exhaust ports 180 may have the multistage structure. That is, an exhaust port plate 181 including the plurality of exhaust ports 180 may be disposed in multistage so that the exhaust ports 180 are disposed symmetrical to each other along the circumference of the substrate support 140. The exhaust port 180 in each stage may be changed in size and shape to adjust a flow of a gas and allow the neutral reaction species to be uniformly distributed on the substrate 10. A vacuum level within the chamber 110 may be maintained by the exhaust ports 180, and the flow of the neutral reaction species may be uniform on an entire surface of the substrate 10. In addition, the process byproducts may be exhausted by the exhaust ports 180. The exhaust port plate 181 may be provided as a ring-shaped plate 181a. The exhaust port plate 181 may include a sidewall that is bent from the ring-shaped plate 181a. The sidewall may have a short length 181b and a long length 181c. The sidewall may induce an exhaust flow. Here, the sidewall may prevent an exhaust gas exhausted into the exhaust ports 180 from leaking to another place and also induce the exhaust flow so that the exhaust gas is well exhausted to the exhaust unit 210. The uppermost exhaust port plate 181a may be connected to the sidewall member 170. The uppermost exhaust port plate 181a and the sidewall member 170 may be connected to each other prevent the exhaust gas exhausted into the gas induction hole 171 from leaking to another place to allow the exhaust gas to be well exhausted to the exhaust ports 180.

The substrate processing apparatus in accordance with an exemplary embodiment may further include a blocking ring 190 extending from the edge portion of the substrate support 140 along the circumference of the substrate support 140. The blocking ring 190 may guide the substrate 10 so that the substrate 10 is stably supported by the substrate support 140 when the substrate 10 moves. Also, the blocking ring 190 may reduce a gap between the substrate support 140 and the sidewall member 170 to minimize the phenomenon in which the neutral reaction species are exhausted without reacting on the substrate 10 due to the exhaust by the exhaust unit 210. That is, the blocking ring 190 may control the flow of the neutral reaction species so that the neutral reaction species pass through the distribution holes 151 of the second diffusion plate 150 to react on the substrate 10 and then are exhausted into the exhaust ports 180 through the gas induction hole 171. Also, the blocking ring 190 may serve as a sidewall of the exhaust port plate 181a to minimize the phenomenon in which the exhaust gas exhausted into the exhaust ports 180 leaks to another place and induce the exhaust flow so that the exhaust gas is well exhausted to the exhaust unit 210. That is, the blocking ring 190 may induce an exhaust path of the exhaust gas including the process byproducts generated by the etching and deposition so that the exhaust gas passes through the gas induction hole 171 of the sidewall member 170 and then is exhausted to the exhaust unit 210 through the exhaust ports 180.

In the substrate processing apparatus in accordance with an exemplary embodiment, each of the first diffusion plate 130 and the second diffusion plate 150 may affect the flow of the gas (e.g., the process gas, the plasma, and the neutral reaction species) to allow the neutral reaction species to be uniformly distributed on the substrate 10. Also, the more accurate substrate processing may be performed through the sidewall member 170 and the exhaust ports 180. As described above, the substrate processing apparatus in accordance with an exemplary embodiment may perform the uniform substrate processing such as the etching and deposition on the entire surface of the substrate 10 by adjusting the flow of the gas through the various components. In addition, the components may be changed in structure to perform more uniform substrate processing.

As described above, in the substrate processing apparatus in accordance with the exemplary embodiment, the first diffusion plate for distributing the process gas and the second diffusion plate for distributing the plasma may be used to realize the uniform distribution of the plasma. Thus, the substrate processing such as the etching and the deposition may be uniformly performed on the entire surface of the substrate. Also, when the plasma is generated, the substrate may not be directly exposed to the plasma through the second diffusion plate. Thus, the substrate and the circuit elements formed on the substrate may be prevented from being damaged by the generation of the arc, the collision of the ions, and the injection of the ions within the chamber. Thus, the process defects of the substrate and the circuit elements formed on the substrate may be minimized. Also, the second diffusion plate may be grounded to filter the ions and electrons charged in the plasma. Thus, since only the neutral reaction species are introduced onto the substrate, the harmful influence of the charged ions and electrons on the substrate and the surrounding of the substrate may be minimized. Also, the substrate and the surrounding of the substrate may be prevented from being damaged by the plasma. In addition, the effective area density of the distribution hole may be simply adjusted by using the insertion body that is inserted into the distribution hole of the second diffusion plate. Therefore, even though the process conditions are changed, the neutral reaction species may be uniformly distributed. Also, the second diffusion plate may have the multistage structure to control the flow of the neutral reaction species. Also, the exhaust port in each stage may be changed in size and shape to adjust the flow of the gas and allow the neutral reaction species to be uniformly distributed on the substrate. The vacuum level within the chamber may be maintained by the exhaust ports, and the flow of the neutral reaction species may be uniform on the entire surface of the substrate. In addition, the process byproducts may be exhausted by the exhaust ports.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art. Hence, the real protective scope of the present invention shall be determined by the technical scope of the accompanying claims.

What is claimed is:

1. A substrate processing apparatus comprising:
a chamber configured to provide a substrate processing space;
a process gas supply line configured to supply a process gas into the chamber;
a first diffusion plate having an injection hole, through which the process gas is injected, in an edge portion thereof;
a substrate support disposed to face the first diffusion plate and configured to support a substrate;
a second diffusion plate disposed between the first diffusion plate and the substrate support, and having a plurality of distribution holes; and
a plasma generation unit configured to generate plasma in a space between the first diffusion plate and the second diffusion plate.

2. The substrate processing apparatus of claim 1, further comprising a sidewall member connected to an edge of the second diffusion plate and having a plurality of gas induction holes.

3. The substrate processing apparatus of claim 1, wherein the second diffusion plate has effective area densities of the distribution holes, which are different from each other according to positions of the distribution holes.

4. The substrate processing apparatus of claim 3, wherein the effective area density of the distribution hole in a central portion of the second diffusion plate is greater than that of the distribution hole in an edge portion of the second diffusion plate.

5. The substrate processing apparatus of claim 1, further comprising an insertion body inserted into each of the distribution holes to adjust an opening area of the second diffusion plate.

6. The substrate processing apparatus of claim 5, wherein the insertion body has a through hole passing through a central portion of the insertion body.

7. The substrate processing apparatus of claim 1, wherein the second diffusion plate has a multistage structure comprising a plurality of stages, and
the distribution holes in the stages adjacent to each other are different in position from each other.

8. The substrate processing apparatus of claim 1, further comprising a position adjustment unit configured to adjust a distance between the first diffusion plate and the second diffusion plate.

9. The substrate processing apparatus of claim 1, further comprising a plurality of exhaust ports disposed symmetrical to each other along a circumference of the substrate support at positions adjacent to an inner wall of the chamber and having a multistage structure.

10. The substrate processing apparatus of claim 1, further comprising a blocking ring extending from an edge portion of the substrate support along a circumference of the substrate support.
